(19) United States
(12) Patent Application Publication
(10) Pub. No.: US 2009/0004875 A1
(43) Pub. Date: Jan. 1, 2009

(54) METHODS OF TRIMMING AMORPHOUS CARBON FILM FOR FORMING ULTRA THIN STRUCTURES ON A SUBSTRATE

(76) Inventors: Meihua Shen, Fremont, CA (US); Diana Xiaobing Ma, Saratoga, CA (US); Wendy H. Yeh, Mountain View, CA (US); Kenneth MacWilliams, Los Altos Hills, CA (US); Wei Liu, San Jose, CA (US); Thorsten B. Lill, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/163,888

(22) Filed: Jun. 27, 2008

Related U.S. Application Data
(60) Provisional application No. 60/946,554, filed on Jun. 27, 2007.

(51) Int. Cl. H01L 21/308

(52) U.S. Cl. 438/735; 257/E21.232

(57) ABSTRACT

Methods for forming an ultra thin structure using a method that includes trimming a mask layer during an etching process are provided. The embodiments described herein may be advantageously utilized to fabricate a submicron structure on a substrate having a critical dimension less than 55 nm and beyond. In one embodiment, a method of forming a submicron structure on a substrate may include providing a substrate having a patterned photoresist layer disposed on a film stack into an etch chamber, wherein the film stack includes at least a hardmask layer disposed on an underlying layer, trimming the photoresist layer to a first predetermined critical dimension, etching the hardmask layer through openings defined by the trimmed photoresist layer, trimming the hardmask layer to a second predetermined critical dimension, and etching the underlying layer through openings defined by the trimmed hardmask layer.

### CROSS-REFERENCE TO RELATED APPLICATIONS

This application claims benefit of U.S. Provisional Application Ser. No. 60/946,554, filed Jun. 27, 2007 (Attorney Docket No. APPM/9342L), which is incorporated by reference in its entirety.

### BACKGROUND

1. Field

Embodiments of the present invention generally relates to methods for trimming an amorphous carbon film, and more specifically, for trimming an amorphous carbon film utilized as a hardmask layer for forming ultra thin structures on a substrate suitable for semiconductor device fabrication.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structure on the substrate is important to VLSI and ULSI success and to the continued effort to increase circuit density and quality of individual substrates and die.

A patterned mask is commonly used in forming structures, such as gate structure, shallow trench isolation (STI), bite lines and the like, on a substrate by etching process. The patterned mask is conventionally fabricated by using a lithographic process to optically transfer a pattern having the desired critical dimensions to a layer of photoresist. The photoresist layer is then developed to remove undesired portion of the photoresist, thereby creating openings in the remaining photoresist through which underlying material is etched.

In order to enable fabrication of next generation, submicron gate structures having critical dimension of about 55 nm or less, optical resolution limitations of the conventional lithographic process must be overcome to reliably transfer critical dimensions during mask fabrication. Developing new lithographic tools and techniques pose significantly research investment and integration cost. As such, the inventors recognize to the potential of extending available fabrication tools to sub 55 nm and smaller device dimensions as one solution for addressing this challenge.

Furthermore, as the geometry limits of the structures used to form semiconductor devices are pushed against technology limits, the need for accurate process control for the manufacture of small critical dimensional structures has become increasingly important. Poor process control during etching process will result in irregular structure profiles and line edge roughness, thereby resulting poor line integrity of the formed structures. Additionally, irregular profiles and growth of the etching by-products formed during etching may gradually block the small openings used to fabricate the small critical dimension structures, thereby resulting in bowed, distorted, toppled, or twisted profiles of the etched structures. As the structures formed on the substrate may be made by one or more different materials, poor profile control or edge line discontinuity at the interface of different materials may result in stress incompatible in between each film. As the geometry and the aspect ratio of the structures become even smaller and higher, the stress mismatch issue occurred between different materials in the film stack become increasingly dominant, thereby resulting in stress induced line edge roughness or line breakage.

Therefore, there is a need in the art for improved methods to fabricate thin structures on a substrate.

### SUMMARY

Embodiments of the invention include forming small dimensional structure on a substrate using a method that includes trimming a mask layer during an etching process. The embodiments described herein may be advantageously utilized to fabricate a submicron structure on a substrate having a critical dimension less than 55 nm.

In one embodiment, a method of forming a submicron structure on a substrate may include providing a substrate having a patterned photoresist layer disposed on a film stack into an etch chamber, wherein the film stack includes at least a hardmask layer disposed on an underlying layer, trimming the photoresist layer to a predetermined critical dimension, etching the hardmask layer through openings defined by the trimmed photoresist layer, trimming the hardmask layer to a predetermined critical dimension, and etching the underlying layer through openings defined by the trimmed hardmask layer.

In another embodiment, a method of forming a submicron structure on a substrate may include providing a substrate having a patterned photoresist layer disposed on a film stack into an etch chamber, wherein the film stack includes a thin capping layer and a thick hardmask layer disposed on a underlying layer, trimming the photoresist layer to a predetermined critical dimension, etching the capping layer through openings defined in the trimmed photoresist layer to form a patterned capping layer, partially etching the hardmask layer through the patterned capping layer to a predetermined depth that does not break through the hardmask layer, removing the remaining patterned capping layer from the hardmask layer, trimming the hardmask layer to a predetermined critical dimension, wherein the trimming process forms opening in the hardmask layer, and etching the underlying layer through the openings defined in the trimmed hardmask layer.

In yet another embodiment, a method of forming a submicron structure on a substrate may include providing a substrate having a patterned photoresist layer disposed on a film stack into an etch chamber, wherein the film stack includes an amorphous carbon layer disposed on a polysilicon layer, trimming the photoresist layer to a predetermined critical dimension, anisotropically etching the amorphous carbon layer through the trimmed photoresist layer to a predetermined depth that does not break through the amorphous carbon layer, trimming the amorphous carbon layer into a predetermined critical dimension, wherein trimming also forms openings in the amorphous carbon layer, etching the polysilicon layer through the openings in the trimmed amorphous carbon layer, and forming a gate structure on the substrate.

### BRIEF DESCRIPTION OF THE DRAWINGS

The teachings of the present invention can be readily understood by considering the following detailed description in conjunction with the accompanying drawings, in which:

FIG. 1 is a schematic diagram of a plasma processing apparatus used in performing the etching processed according to one embodiment of the invention;

FIG. 2 is a process flow diagram illustrating a method incorporating one embodiment of the invention; and

FIGS. 3A-3H are diagrams illustrating a cross-sectional view of a film stack utilized to form a ultra thin structure on a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally relate to methods for forming an ultra thin structure on a substrate by trimming a mask layer during an etching process. In one embodiment, the ultra thin structure formed using the trimming process may have a critical dimension down to 55 nm or less. The method described therein includes a sequential reduction of the features geometry as well as feature aspect ratio to control and retain good line integrity.

The etch and trimming process described herein may be performed in any suitably adapted plasma etch chamber, for example, a Decoupled Plasma Source (DPS), DPS-II, or DPS Plus, or DPS DT etch reactor of a CENTURA® etch system, a HART etch reactor, and a HART TS etch reactor, all of which are available from Applied Materials, Inc., of Santa Clara, Calif. It is contemplated that suitably adapted plasma etch chambers available from other manufacturers may also be utilized.

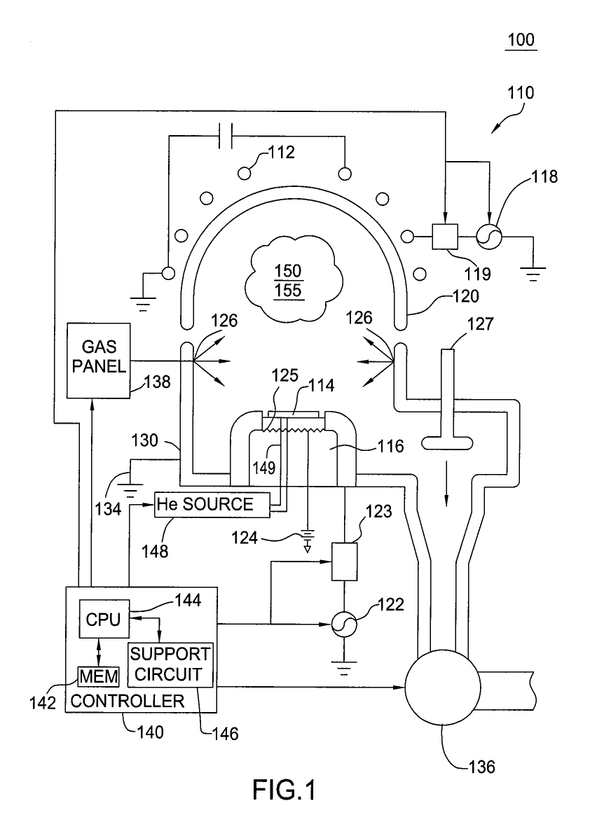

FIG. 1 depicts a schematic diagram of one embodiment of an illustrative etch process chamber 100 suitable for practicing the invention. The chamber 100 includes a conductive chamber wall 130 that supports a dielectric dome-shaped ceiling (referred hereinafter as the dome 120). Other chambers may have other types of ceilings (e.g., a flat ceiling). The wall 130 is connected to an electrical ground 134.

At least one inductive coil antenna segment 112 is coupled to a radio-frequency (RF) source 118 through a matching network 119. The antenna segment 112 is positioned exterior to a dome 120 and is utilized to maintain a plasma formed from process gases within the chamber. In one embodiment, the source RF power applied to the inductive coil antenna 112 is in a range between about 0 Watts to about 2500 Watts at a frequency between about 50 kHz and about 13.56 MHz. In another embodiment, the source RF power applied to the inductive coil antenna 112 is in a range between about 200 Watts to about 800 Watts, such as at about 400 Watts.

The process chamber 100 also includes a substrate support pedestal 116 (biasing element) that is coupled to a second (biasing) RF source 122 that is generally capable of producing an RF signal to generate a bias power about 1500 Watts or less (e.g., no bias power) at a frequency of approximately 13.56 MHz. The biasing source 122 is coupled to the substrate support pedestal 116 through a matching network 123. The bias power applied to the substrate support pedestal 116 may be DC or RF.

In operation, a substrate 114 is placed on the substrate support pedestal 116 and is retained thereon by conventional techniques, such as electrostatic chucking, vacuum or mechanical clamping. Gaseous components are supplied from a gas panel 138 to the process chamber 100 through entry ports 126 to form a gaseous mixture 150. A plasma, formed from the mixture 150, is maintained in the process chamber 100 by applying RF power from the RF sources 118 and 122, respectively, to the antenna 112 and the substrate support pedestal 116. The pressure within the interior of the etch chamber 100 is controlled using a throttle valve 127 situated between the chamber 100 and a vacuum pump 136. The temperature at the surface of the chamber walls 130 is controlled using liquid-containing conduits (not shown) that are located in the walls 130 of the chamber 100.

The temperature of the substrate 114 is controlled by stabilizing the temperature of the support pedestal 116 and flowing a heat transfer gas from source 148 via conduit 149 to channels formed by the back of the substrate 114 and grooves (not shown) on the pedestal surface. Helium gas may be used as the heat transfer gas to facilitate heat transfer between the substrate support pedestal 116 and the substrate 114. During the etch process, the substrate 114 is heated by a resistive heater 125 disposed within the substrate support pedestal 116 to a steady state temperature via a DC power source 124. Helium disposed between the pedestal 116 and substrate 114 facilitates uniform heating of the substrate 114. Using thermal control of both the dome 120 and the substrate support pedestal 116, the substrate 114 may be maintained at a temperature of between about 100 degrees Celsius and about 500 degrees Celsius.

Those skilled in the art will understand that other forms of etch chambers may be used to practice the invention. For example, chambers with remote plasma sources, microwave plasma chambers, electron cyclotron resonance (ECR) plasma chambers, and the like may be utilized to practice the invention.

A controller 140, including a central processing unit (CPU) 144, a memory 142, and support circuits 146 for the CPU 144 is coupled to the various components of the DPS etch process chamber 100 to facilitate control of the etch process. To facilitate control of the chamber as described above, the CPU 144 may be one of any form of general purpose computer processor that can be used in an industrial setting for controlling various chambers and subprocessors. The memory 142 is coupled to the CPU 144. The memory 142, or computer-readable medium, may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. An etching process, such as described herein, is generally stored in the memory 142 as a software routine. The software routine may also be stored and/or executed by a second CPU (not shown) that is remotely located from the hardware being controlled by the CPU 144.

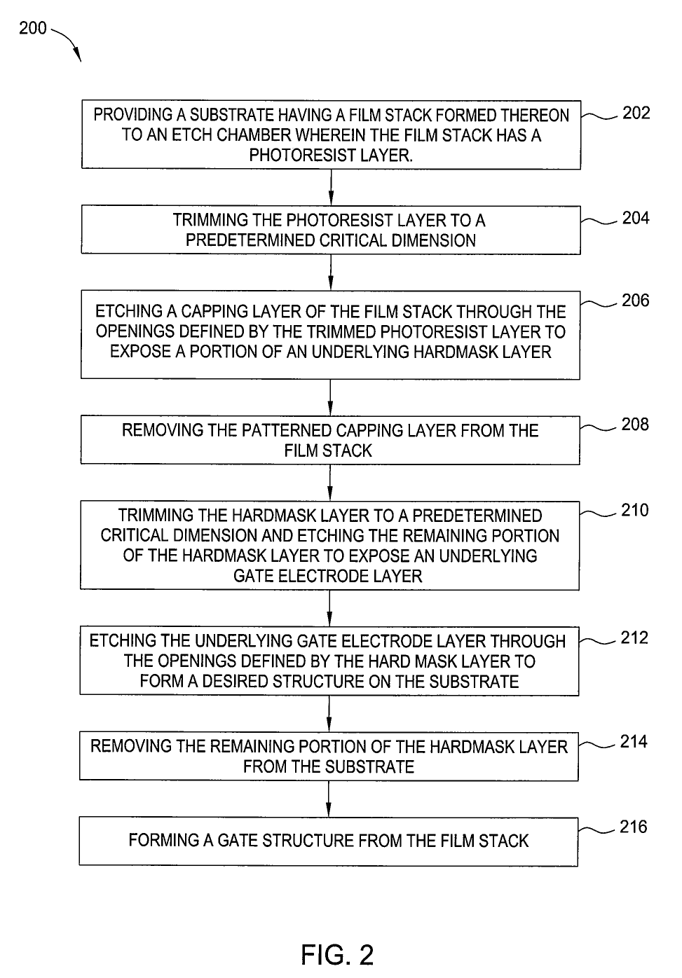

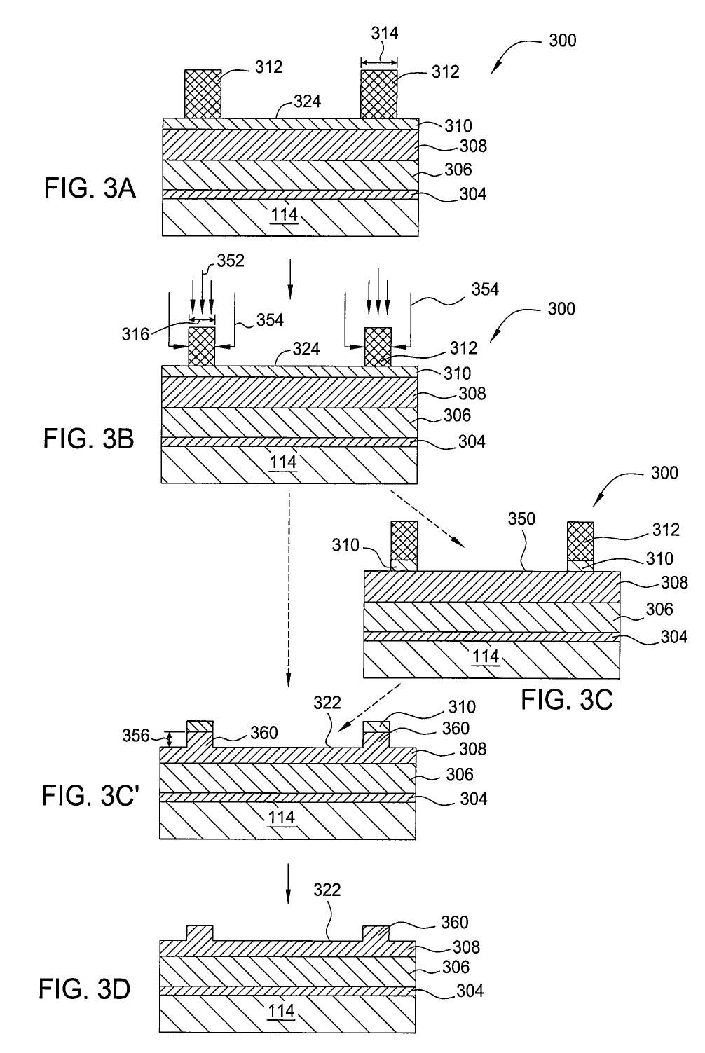

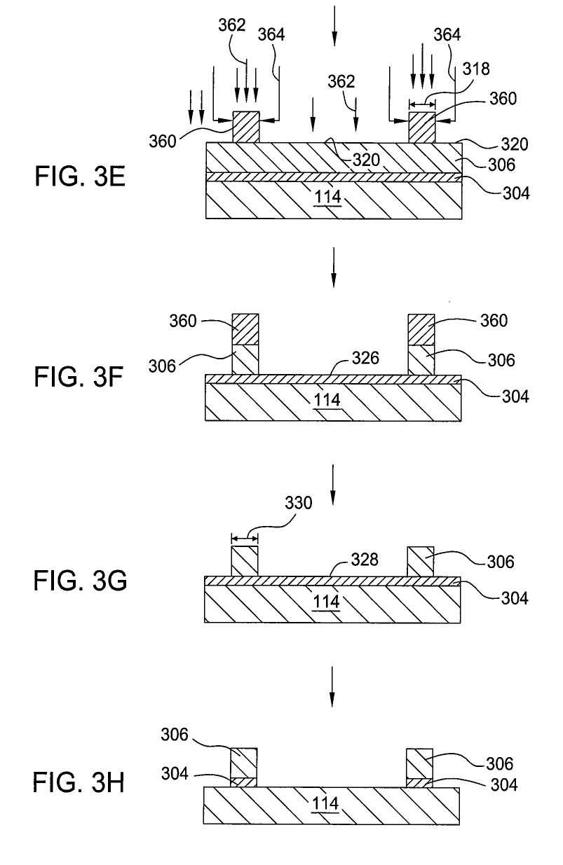

FIG. 2 is a flow diagram of one embodiment of an etch process 200 that may be practiced in the chamber 100 or other suitable processing chamber. FIGS. 3A-3H are schematic cross-sectional views of a portion of a composite substrate corresponding to various stages of the process 200. Although the process 200 is illustrated for forming a gate structure in FIGS. 3A-3H, the process 200 may be beneficially utilized to fabricate other structures.

The process 200 begins at block 202 by transferring (i.e., providing) a substrate 114 to an etch process chamber, such as the process chamber 100 as depicted in FIG. 1. In the embodiment depicted in FIG. 3A, the substrate 114 has a film stack 300 suitable for fabricating a gate structure. The substrate 114 may be any one of semiconductor substrates, silicon wafers, glass substrates and the like. The layers that comprise the film stack 300 may be formed using one or more suitable conventional deposition techniques, such as atomic layer deposition (ALD), physical vapor deposition (PVD), chemical vapor deposition (CVD), plasma enhanced CVD (PECVD), and the like. The film stack 300 may be deposited using the respective processing modules of CENTURA®, PRODUCER®, ENDURA® and other semiconductor wafer processing systems available from Applied Materials, Inc. of Santa Clara, Calif., among systems available from other manufacturers.

In one embodiment, the film stack 300 includes a gate electrode layer 306 disposed on a gate dielectric layer 304. A hardmask layer 308 and an optional capping layer 310 are disposed on the gate electrode layer 306. A patterned photoresist layer 312 (e.g. a photomask layer) is disposed on the top of the capping layer 310. At least a portion 324 of the capping layer 310 is exposed for etching through openings in the photoresist layer 312. In embodiments where the optional capping layer 310 is not present, the patterned photoresist layer 312 may be directly formed on the upper surface of the hardmask layer 308, exposing portions of the hardmask layer 308 for etching. In the embodiment depicted in FIG. 3A, portions 324 of the capping layer 310 are exposed through one or more openings defined by the patterned photoresist layer 312 so that the capping layer 310 may be readily etched as will be further described below.

In one embodiment, the capping layer 310 may be in form of a single layer selected from a group consisting of silicon oxide, silicon nitride, silicon oxynitride (SiON), amorphous silicon (α-Si) or silicon carbide, among other silicon films. Alternatively, the capping layer 310 may be in form of a composite film including at least two layers selected from the materials described above. In an exemplary embodiment of using a composite film, the capping layer 310 may include a silicon layer disposed on a silicon oxide layer.

The hardmask layer 308 may be a carbon containing layer selected from a group consisting of amorphous carbon (α-carbon), and silicon carbide, among others. One example of the hardmask layer 308 described herein is an α-carbon film, such as Advanced Patterning Film™ (APF) available from Applied Materials, Inc.

In one embodiment, the gate electrode layer 306 may be a polysilicon material. In another embodiment, the gate electrode layer 306 may be a metal utilized for metal gate electrode. Examples of metal gate electrode include tungsten (W), tungsten silicide (WSi), tungsten polysilicon (W/poly), tungsten alloy, tantalum (Ta), tantalum nitride (TaN), tantalum silicon nitride (TaSiN), and titanium nitride (TiN), among others. In yet another embodiment, the gate electrode layer 306 may be a composite film including a polysilicon layer disposed on a metal material. In this particular embodiment, the gate electrode layer 306 may be a polysilicon layer disposed on a titanium nitride (TiN) layer.

The gate dielectric layer 304 may be a dielectric layer selected from a group consisting of silicon oxide, silicon nitride, silicon oxynitride, high-k materials or combinations thereof. The high-k materials referred herein are dielectric materials having dielectric constants greater than 4.0. Suitable examples of the high-k material layer include hafnium dioxide (HfO₂), zirconium dioxide (ZrO₂), hafnium silicon oxide (HfSiO₂), hafnium aluminum oxide (HfAlO), zirconium silicon oxide (ZrSiO₂), tantalum dioxide (TaO₂), aluminum oxide, aluminum doped hafnium dioxide, bismuth strontium titanium (BST), and platinum zirconium titanium (PZT), among others.

In the particular embodiment depicted in FIG. 3A, the capping layer 310 is a single layer of a silicon oxynitride (SiON) layer having a thickness between about 50 Å and about 500 Å. The hardmask layer 308 is an amorphous carbon film having a thickness between about 500 Å and about 1000 Å, such as between about 600 Å to about 700 Å, for example about 650 Å. The gate electrode layer 306 is a polysilicon layer having a thickness between about 600 Å and about 2500 Å, such as between about 650 Å and about 1800 Å, for example, between about 800 Å and about 1000 Å. The photoresist layer 312 has been patterned by a conventional lithographic process and has openings having a critical dimension 314 of about 85 nm to 90 nm that expose the portion 324 of the underlying capping layer 310 for etching.

At block 204, a first trimming gas mixture is supplied to the etch chamber to trim the photoresist layer 312 to a predetermined critical dimension. During trimming, the dimension 314 of the photoresist layer 312 is trimmed to a dimension 316 smaller than that of the lithographically patterned mask, as shown in FIG. 3B, before the mask is utilized as an etch mask for the subsequent etching processes. As the dimension of the photoresist layer 312 may be further reduced during the subsequent etching process, which will be further described below, the trimming process performed at block 204 may be configured to initially trim the photoresist layer 312 to a predetermined dimension but not to the target dimension ultimately desired to be formed on the substrate 114. Since the photoresist layer 312 will be further exposed to reactive etchants generated in the subsequently performed etching processes, if the photoresist layer 312 is trimmed to a dimension that is too small during the early stage of the etching process, the remaining structure of the photoresist layer 312 may collapse or become deformed, thereby resulting in incomplete and/or inaccurate etching of the underlying layers. As such, the dimension of the photoresist layer 312 may be sequentially reduced by the trimming process performed at block 204 and the subsequently performed etching process to maintain the integrity of the photoresist layer 312 as an effective etch mask.

In one embodiment, the trimming process trims the critical dimension 316 of the photoresist layer 312 to about 55 nm or less, such as about 40 nm. The trimming process performed at block 204 is generally an isotropic etch process (e.g., isotropic plasma etch process) that etches the photoresist layer 312 both vertically, as shown by arrows 352, and laterally, as shown by arrows 354. As the trimming process slightly reduces the width of the photoresist structure, the first trimming gas mixture is selected to have a high selectivity for the photoresist layer 312 over the capping layer 310, thereby predominantly trimming the photoresist layer 312 rather than etching the exposed surface 324 of the capping layer 310. In one embodiment, the first trimming gas mixture includes, but not limited to, a halogen containing gas accompanying by an oxygen containing gas. Examples of the halogen containing gas include HBr, HCl, Cl₂, Br₂, and the like. Examples of the oxygen containing gas includes O₂, NO, N₂O and the like. Alternatively, inert gas, such as Ar or He, may also be incorporated with the first trimming gas into the etch chamber.

Several process parameters are regulated while the first trimming gas mixture at block 204 supplied into the etch chamber. In one embodiment, the chamber pressure in the presence of the first trimming gas mixture is regulated between about 2 mTorr to about 100 mTorr, for example, at about 4 mTorr. RF source power may be applied to maintain a plasma formed from the first trimming process gas. For example, a power of about 100 Watts to about 1500 Watts, such as about 500 Watts, may be applied to an inductively coupled antenna source to maintain a plasma inside the etch chamber. The first trimming gas mixture may be flowed into the chamber at a rate between about 50 sccm to about 1000 sccm. For example, the halogen containing gas may be supplied at a flow rate between about 50 sccm and about 1000 sccm. The oxygen containing gas may be supplied at a flow rate between about 50 sccm and about 1000 sccm and the inert gas may be supplied at a flow rate about 50 sccm and about 1000 sccm. A substrate temperature may be maintained between about 10 degrees Celsius to about 500 degrees Celsius, such as about 50 degrees Celsius.

At block 206, a capping layer etching gas mixture and/or a hardmask layer etching gas mixture is supplied into the etch chamber to etch the capping layer 310 and/or the hardmask layer 308. The capping layer etching process is generally an anisotropic etch process (e.g., anisotropic plasma etch process) that mainly etches the capping layer 310 and/or the hardmask layer 308 vertically. The capping layer 310 is etched through the exposed openings 324 defined by the trimmed photoresist layer 312. In one embodiment, the capping layer 310 is etched until the underlying upper surface 350 of the hardmask layer 308 is exposed, forming a patterned capping layer 310 on the hardmask layer 308, as shown in FIG. 3C.

Alternatively, the capping layer 310 may be etched to further expose the underlying hardmask layer 308. A portion of the capping layer 310 unprotected by the photoresist layer 312 is etched, forming a patterned capping layer 310 on the hardmask layer 308. The capping layer 310 is over-etched in a manner that etches a portion of the underlying hardmask layer 308 to a predetermined depth 356, as shown in FIG. 3C′, leaving the portion 322 of the hardmask layer 308 on the substrate 114. The remaining portion 322 of the hardmask layer 308 protects the underlying gate electrode layer 306 from being attack in the early stage of the subsequent trimming process and etching process. During etching, the photoresist layer 312 may be consumed and/or etched out, leaving the patterned capping layer 310, and remaining portions hardmask layer 360, 308 on the substrate 114. The patterned capping layer 310 and/or the patterned hardmask layer 360 serve as an etch mask layer for the subsequently etching process, as will be further discussed below.

In an embodiment wherein the capping layer etching process is configured to mainly etch the capping layer 310, the etching process is selectively terminated at the point where the underlying hardmask layer 308 is exposed as shown in FIG. 3C. The capping layer etching gas mixture is selected to have a high selectivity for the capping layer 310 over the hardmask layer 308. In one embodiment, the capping layer etching gas mixture includes a fluorine-carbon containing gas. Examples of the fluorine-carbon containing gas include CF₄, CH₃F, CH₂F₂, CHF₃, C₂F₆, C₄F₈, and the like. The fluorine-carbon containing gas may be selected to have a relatively higher hydrogen content and a lower fluorine content. One suitable example of the relatively higher hydrogen content and lower fluorine content of the fluorine-carbon containing gas includes, but not limited to, CH₃F gas and the like. The relatively lower fluorine content in the fluorine-carbon containing gas preferentially etches the capping layer 310 to expose the underlying hardmask layer 310 without aggressively removing the hardmask layer 310.

Optionally, a carrier gas and/or an inert gas may be supplied with the capping layer etching gas mixture to the etch chamber. Examples of the carrier gas include oxygen gas (O₂), nitrogen gas (N₂), N₂O, CO₂, NO₂, and the like. Examples of the inert gas include Ar, He and the like.

After the exposed capping layer 324 has been removed from the substrate 114 leaving the patterned capping layer 310 on the hardmask layer 308, a hardmask layer etching gas mixture may be then supplied to etch the hardmask layer 308, as shown in FIG. 3C′, through openings defined by the patterned capping layer 310. The hardmask layer etching gas mixture includes at least an oxygen containing gas. Suitable examples of the oxygen containing gas include O₂, N₂O, NO₂, and the like. Optionally, a hydrogen containing gas, such as H₂, H₂O and the like, may be supplied to the hardmask layer etching gas mixture to assist etching the hardmask layer 308. In an embodiment wherein the hardmask layer 308 is an amorphous carbon layer, the oxygen ions and/or hydrogen ions plasma dissociated from the oxygen containing gas and/or hydrogen containing gas reacts with the carbon elements in the hardmask layer 308, forming carbon oxide gas or carbon hydrogen gas which is readily pumped out of the chamber. The oxygen containing gas and/or the hydrogen containing gas has high selectivity to the hardmask layer 308 over the capping layer 310, thereby preferentially etching the hardmask layer 308 to a predetermined depth 356 without damaging the upper patterned capping layer 310. Alternatively, a small amount of halogen containing gas may be supplied with the hardmask layer etching gas mixture to assist etching the hardmask layer 308.

A carrier gas and/or an inert gas may be supplied with the capping layer etching gas mixture to the etch chamber. Examples of the carrier gas include nitrogen gas (N₂), N₂O, CO₂, NO₂, and the like. Examples of the inert gas include Ar, He and the like.

In another embodiment wherein the capping layer etching process at block 206 is configured to etch the hardmask layer 308 in a single step to a predetermined depth of the hardmask layer 308 as shown in FIG. 3C′, the capping layer etching gas mixture is selected to have a low selectivity to the capping layer 310 over the hardmask layer 308. The low selectivity of the capping layer etching gas mixture allows the etching process to consecutively etch the capping layer 310 and the hardmask layer 308 without switching gas mixture and process parameters during etching. In this embodiment, the capping layer etching gas mixture includes a fluorine-carbon containing gas. Examples of the fluorine-carbon containing gas include CF₄, CH₃F, CH₂F₂, CHF₃, C₂F₆, C₄F₈, and the like. The fluorine-carbon containing gas may be selected to have a relatively higher fluorine content and a lower hydrogen content. Suitable examples of the relatively higher fluorine content and lower hydrogen content of the fluorine-carbon containing gas include, but not limited to, CF₄ gas or CHF₃ gas. The relatively higher fluorine content in the fluorine-carbon containing gas allows the etching gas mixture to etch both the capping layer 310 and the hardmask layer 308, thereby consecutively etching from the capping layer 310 to the underlying hardmask layer 308 until the desired depth 356 is reached in the hardmask layer 308. The etching process may be controlled by time mode, such as performing the process for a predetermined time period. In one embodiment, the depth 356 removed from the hardmask layer 308 is between about 250 Å and about 550 Å, such as about 450 Å. Alternatively, the depth 356 removed from the hardmask layer 308 may be controlled by the thickness percentage variation present in the hardmask layer 308 on the substrate 114. In one embodiment, the thickness percentage removed from the hardmask layer 308 is between about 60 percent and about 80 percent of the total thickness of the hardmask layer 308.

Optionally, a carrier gas and/or an inert gas may be supplied with the capping layer etching gas mixture to the etch chamber. Examples of the carrier gas include oxygen gas (O₂), nitrogen gas (N₂), N₂O, NO₂, CO₂, and the like. Examples of the inert gas include Ar, He and the like.

Several process parameters are regulated while the capping layer etching gas mixture at block 206 is supplied into the etch chamber. In one embodiment, the chamber pressure is regulated between about 2 mTorr to about 100 mTorr. RF source power may be applied to maintain a plasma formed from the capping layer etching gas mixture. For example, a power of about 100 Watts to about 1500 Watts, such as about 500 Watts, may be applied to an inductively coupled antenna source to maintain a plasma inside the etch chamber. The capping layer etching gas mixture may be flowed into the chamber at a rate between about 50 sccm to about 1000 sccm. For example, the fluorine-carbon containing gas may be supplied at a flow rate between about 50 sccm and about 1000 sccm. The carrier gas may be supplied at a flow rate between about 50 sccm and about 1000 sccm and the inert gas may be supplied at a flow rate about 50 sccm and about 1000 sccm. A substrate temperature may be maintained between about 10 degrees Celsius to about 500 degrees Celsius, such as about 50 degrees Celsius.

Using the trimmed capping layer 310 as a patterned mask layer to open and etch the underlying hardmask layer 308 beneficially provides good dimension control while sequentially transferring features to each underlying layers, thereby preventing collapse or deformation of mask layer due to prolonged plasma attack during each etching step as compared to etching using conventional photoresist only masking techniques. Additionally, by using the sequentially etching to transfer features to each underlying layers, the stress mismatch accumulated in between the interface of each layers is therefore eliminated and the stress induced edge line roughness and breakage is reduced accordingly.

At block 208, a patterned capping layer removal gas mixture is supplied into the etch chamber to remove the patterned capping layer 310 from the substrate 114, as shown in FIG. 3D. The patterned capping layer removal process is generally an anisotropic etch process (e.g., anisotropic plasma etch process) that mainly etches the patterned capping layer 310 vertically.

In one embodiment, the capping layer 310 is removed before the underlying hardmask layer 308 is trimmed to a smaller dimension. As the capping layer 310 and the underlying hardmask layer 308 may be made of different materials that have different etching rates, removal of the capping layer 310 prior to the removal of the underlying hardmask layer 308 prevents T-shape profiles from being formed in the hardmask layer 308 and the capping layer 310 due to differences in the etching selectivity between the two layers. Additionally, good control of the etched profile will beneficially increase the accuracy of measurement taken by metrology tools of the features formed on the substrate if needed.

The patterned capping layer removal gas mixture includes at least a fluorine-carbon containing gas. Examples of the fluorine-carbon containing gas include CF₄, CH₃F, CH₂F₂, CHF₃, C₂F₆, C₄F₈, and the like. The fluorine-carbon containing gas may be selected to have a relatively higher hydrogen content and a lower fluorine content, similar to the gas mixture initially supplied to etch the capping layer 310 at block 206. One suitable example of the relatively higher hydrogen content and lower fluorine content of the fluorine-carbon containing gas includes, but not limited to, CH₃F gas. The relatively lower fluorine content in the fluorine-carbon containing gas etches the hardmask layer 308 remaining on the substrate 114 less aggressively, thereby selectively etching the patterned capping layer 310 with minimal etching of the hardmask layer 308.

Optionally, a carrier gas and/or an inert gas may be supplied with the capping layer etching gas mixture to the etch chamber. Examples of the carrier gas include oxygen gas (O₂), nitrogen gas (N₂), N₂O, NO₂, and the like. Examples of the inert gas include Ar, He and the like.

Several process parameters are regulated while the patterned capping layer removal gas mixture is supplied into the etch chamber. In one embodiment, the chamber pressure is regulated between about 2 mTorr to about 100 mTorr, for example, at about 10 mTorr. RF source power may be applied to maintain a plasma formed from the capping layer etching gas mixture. For example, a power of about 100 Watts to about 1500 Watts, such as about 300 Watts, may be applied to an inductively coupled antenna source to maintain a plasma inside the etch chamber. The capping layer etching gas mixture may be flowed into the chamber at a rate between about 50 sccm to about 1000 sccm. For example, the fluorine-carbon containing gas may be supplied at a flow rate between about 50 sccm and about 1000 sccm. The carrier gas may be supplied at a flow rate between about 50 sccm and about 1000 sccm and the inert gas may be supplied at a flow rate about 50 sccm and about 1000 sccm. A substrate temperature is maintained between about 30 degrees Celsius to about 500 degrees Celsius, such as about 50 degrees Celsius.

At block 210, a second trimming gas mixture is supplied into the etch chamber to trim the patterned hardmask layer 360 to a predetermined critical dimension 318, as shown in FIG. 3E. The remaining portion 322 of the hardmask layer 308 left on the substrate surface is consumed and removed from the substrate surface while trimming patterned hardmask layer 360. As the remaining hardmask layer 322 is removed, the underlying gate electrode layer 306 is exposed through the openings 320 defined by the patterned hardmask layer 360. As discussed above, the trimming process is an isotropic etch process (e.g., isotropic plasma etch process) that etches both vertically, as shown by arrows 362, and laterally, as shown by arrows 364, of the hardmask layer 360, 308. As the trimming process slightly shrinks the hardmask layer structure, the second trimming gas mixture is selected to have a high selectivity for the hardmask layer 308 over the underlying gate electrode layer 306, thereby selectively trimming the hardmask layer 308 rather than damaging and etching the exposed surface 320 of the gate electrode layer 306.

In one embodiment, the second trimming gas mixture includes, but not limited to, at least an oxygen containing gas. Suitable examples of the oxygen containing gas include O₂, N₂O, NO₂, and the like. Optionally, a hydrogen containing gas, such as H₂, H₂O and the like, may be supplied to the second trimming gas to assist etching the hardmask layer 308. In embodiments wherein the hardmask layer 308 is an amorphous carbon layer, the oxygen ions and/or the hydrogen ions plasma dissociated from the oxygen containing gas and/or hydrogen containing gas reacts with the carbon elements in the hardmask layer 308, forming carbon oxide gas and/or carbon hydrogen gas which is readily pumped out of the chamber. The oxygen containing gas and/or the hydrogen containing gas has high selectivity to the hardmask layer 308 over the underlying gate electrode layer 306, thereby preferentially trimming the dimension of the patterned hardmask layer 308 and removing the remaining portion 322 of the hardmask layer 308 from the surface of the gate electrode layer without adversely damaging the gate electrode layer 306. Optionally, a small amount of halogen containing gas i.e., relative to the amount of oxygen containing gas and/or hydrogen containing gas supplied in the gas mixture, may be supplied to the hardmask layer etching gas mixture to assist etching the hardmask layer 308. A carrier gas and/or an inert gas may also be optionally supplied with the second trimming gas as described above as needed.

In one embodiment, the critical dimension of the patterned hardmask layer 360 is trimmed to about 45 nm or less. In another embodiment, the critical dimension of the patterned hardmask layer 360 is trimmed to about 40 nm or less. In yet another embodiment, the critical dimension of the patterned hardmask layer 360 is trimmed to about 20 nm or less. The endpoint may be determined by any suitable method. For example, the endpoint may be determined by expiration of a predefined time period, monitoring optical emissions, or by another indicator suitable for determining that the hardmask layer 360 to be etched has been sufficiently removed.

Several process parameters are regulated while the second trimming gas mixture is supplied into the etch chamber. In one embodiment, the chamber pressure is regulated between about 2 mTorr to about 100 mTorr, for example, at about 4 mTorr. RF source power may be applied to maintain a plasma formed from the capping layer etching gas mixture. For example, a power of about 100 Watts to about 1500 Watts, such as about 500 Watts, may be applied to an inductively coupled antenna source to maintain a plasma inside the etch chamber. The second trimming gas mixture may be flowed into the chamber at a rate between about 50 sccm to about 1000 sccm. For example, the oxygen containing gas may be supplied at a flow rate between about 0 sccm and about 1000 sccm. The carrier gas may be supplied at a flow rate between about 0 sccm and about 1000 sccm and the inert gas may be supplied at a flow rate about 0 scorn and about 1000 sccm. A substrate temperature is maintained between about 30 degrees Celsius to about 500 degrees Celsius, such as about 50 degrees Celsius.

At block 212, a gate etching gas mixture is supplied into the etch chamber to etch the gate electrode layer 306 through the openings 326 defined by the patterned hardmask layer 360, as shown in FIG. 3F. The gate etching process performed is generally an anisotropic etch process (e.g., anisotropic plasma etch process) that mainly etches of the gate electrode layer 306 vertically. As the patterned hardmask layer 360 has been trimmed to have a desired critical dimension, the patterned hardmask layer 360 serves as an etch mask for etching the gate electrode layer 306 through the patterned hardmask layer 360, forming a desired gate structure with desired critical dimension on the substrate 114. In one embodiment, the gate etching gas mixture is selected to have a high selectivity to the gate electrode layer 306 over the patterned hardmask layer 360, thereby preventing the pattered hardmask layer 360 from being consumed or etched away during gate etching process.

In one embodiment, the gate etching gas mixture includes at least a halogen containing gas. Suitable examples of the halogen containing gas include, but not limited to, a chlorine containing gas, a bromine containing gas such as chlorine gas (Cl₂), boron chloride (BCl₃), and hydrogen chloride (HCl), hydrogen bromine (HBr), nitrogen trifluoride (NF₃), sulfur hexafluoride gas (SF₆), tetrafluoromethane gas (CF₄) and the like. Optionally, a carrier gas and/or an inert gas may be supplied with the gate etching gas mixture to the etch chamber. Examples of the carrier gas include oxygen gas (O₂), nitrogen gas (N₂), N₂O, NO₂, and the like. Examples of the inert gas include Ar, He and the like.

Several process parameters are regulated while the gate etching gas mixture is supplied into the etch chamber. In one embodiment, the chamber pressure is regulated between about 2 mTorr to about 100 mTorr. RF source power may be applied to maintain a plasma formed from the gate etching gas mixture. For example, a power of about 100 Watts to about 1500 Watts may be applied to an inductively coupled antenna source to maintain a plasma inside the etch chamber. The gate etching gas mixture may be flowed into the chamber at a rate between about 50 scorn to about 1000 sccm. For example, the halogen containing gas may be supplied at a flow rate between about 0 sccm and about 1000 sccm. The carrier gas may be supplied at a flow rate between about 0 sccm and about 1000 sccm and the inert gas may be supplied at a flow rate about 0 sccm and about 1000 sccm. A substrate temperature is maintained between about 30 degrees Celsius to about 500 degrees Celsius, such as about 50 degrees Celsius.

At block 214, the remaining patterned hardmask layer 360 is removed from the etched gate electrode layer 306, as shown in FIG. 3G. The gas mixture used to remove the patterned hardmask layer 360 is substantially similar to the gas mixture used at block 210. The gas mixture used at block 214 selectively removes the remaining hardmask layer 360 from the gate electrode layer 306 without adversely damaging the profile and dimension of the gate electrode layer 306. In one embodiment, the gas mixture used to remove the patterned hardmask layer 360 is an oxygen containing gas as described above. Optionally, a small amount of halogen containing gas, i.e., relative to the amount of oxygen containing gas supplied in the gas mixture, may be supplied to the gas mixture to assist etching the remaining patterned hardmask layer 360. A carrier gas and/or an inert gas may also be optionally supplied with the second trimming gas as described above. The process parameters may be controlled substantially similar to the parameters formed at block 210.

At block 216, a gate structure is formed on the substrate 114 as shown in FIG. 3G. The gate structure includes the etched gate electrode 306 and the gate dielectric layer 304 with desired critical dimensions. The gate forming process at block 216 includes implanting dopants into the gate structure, thermal activation process and/or other associated processes suitable to make the gate structure functional. As any suitable gate forming process may be utilized at block 216, further description has been omitted for the sake of brevity.

It is noted that the method 200 may be performed in a single chamber. By switching different gas mixtures and process parameters at different stages of the etching process in the chamber, a gate structure with desired submicron critical dimension may be formed on a substrate with minimal process steps and exposure to potential contamination. Although the exemplary embodiment of the etching method described herein is used to form a gate structure, it is noted that the etching method may be utilized to each any different structures including shallow trench isolation (STI), bit lines and any other different structures.

Thus, embodiments of the present invention provide an improved method for forming a structure on a substrate having a submicron critical dimension less than 55 nm and beyond. The present invention advantageously provides a manner for forming features in structure by trimming photoresist and hardmask layer, thereby reducing manufacture cost and overall process cycle time.

While the foregoing is directed to embodiments of the present invention, other and further embodiments of the invention may be devised without departing from the basic scope thereof, and the scope thereof is determined by the claims that follow.

What is claimed is:

1. A method of forming a submicron structure on a substrate, comprising:
providing a substrate having a patterned photoresist layer disposed on a film stack into an etch chamber, wherein the film stack includes at least a hardmask layer disposed on a underlying layer;
trimming the photoresist layer to a predetermined critical dimension;
etching the hardmask layer through openings defined by the trimmed photoresist layer;
trimming the hardmask layer to a predetermined critical dimension; and
etching the underlying layer through openings defined by the trimmed hardmask layer.

2. The method of claim 1, wherein trimming the photoresist layer further comprises:
supplying a halogen containing gas to trim the photoresist layer.

3. The method of claim 1, wherein trimming the hardmask layer further comprises:
supplying an oxygen containing gas or a hydrogen gas to trim the hardmask layer.

4. The method of claim 1, wherein etching the hardmask layer further comprises:
etching openings in a capping layer disposed on the hardmask layer defined by the trimmed photoresist layer to expose the underlying hardmask layer.

5. The method of claim 4, wherein etching the capping layer further comprises:
etching the exposed underlying hardmask layer through the openings in the patterned capping layer to a predetermined depth that does not break through the hardmask layer.

6. The method of claim 4, wherein etching the capping layer further comprises:
etching the capping layer using a plasma formed from at least a fluorine-carbon containing gas.

7. The method of claim 5, wherein etching the exposed underlying hardmask layer further comprises:
etching a hardmask layer using a plasma formed from at least an oxygen containing gas and a hydrogen containing gas.

8. The method of claim 4, wherein the capping layer is a dielectric layer selected from a group consisting of silicon oxide, silicon oxynitride, silicon nitride, silicon, silicon carbon and silicon carbon nitride.

9. The method of claim 1, wherein the hardmask layer is an amorphous carbon layer.

10. The method of claim 1, wherein trimming the hardmask layer into the predetermined critical dimension further comprises:
trimming the hardmask layer to a critical dimension less than about 45 nm.

11. The method of claim 1, wherein etching the underlying layer further comprises:
supplying a halogen containing gas that selectively etches the underlying layer over the hardmask layer, wherein the underlying layer is a polysilicon layer.

12. A method of forming a submicron structure on a substrate, comprising:
providing a substrate having a patterned photoresist layer disposed on a film stack into an etch chamber, wherein the film stack includes a thin capping layer and a thick hardmask layer disposed on an underlying layer;
trimming the photoresist layer to a predetermined critical dimension;
etching the capping layer through openings defined in the trimmed photoresist layer to form a patterned capping layer;
partially etching the hardmask layer through the patterned capping layer to a predetermined depth that does not break through the hardmask layer;
removing the remaining patterned capping layer from the hardmask layer;
trimming the hardmask layer to a predetermined critical dimension, wherein the trimming process forms opening in the hardmask layer; and
etching the underlying layer through the openings defined in the trimmed hardmask layer.

13. The method of claim 12, wherein the capping layer is a layer of at least one of silicon oxide, silicon oxynitride, silicon nitride, silicon, silicon carbon or silicon carbon nitride.

14. The method of claim 12, wherein the hardmask layer is an amorphous carbon layer.

15. The method of claim 12, wherein the predetermined depth of the etched hardmask layer is between about 60 percent and about 80 percent of the total thickness of the hardmask layer.

16. The method of claim 12, wherein trimming the hardmask layer into a predetermined critical dimension further comprises:
trimming the hardmask layer to have a critical dimension less than about 45 nm.

17. The method of claim 12, wherein the underlying layer is a polysilicon layer utilized to be as a gate electrode layer.

18. A method of forming a submicron structure on a substrate, comprising:
providing a substrate having a patterned photoresist layer disposed on a film stack into an etch chamber, wherein the film stack includes an amorphous carbon layer disposed on a polysilicon layer;
trimming the photoresist layer to a predetermined critical dimension;
anisotropically etching the amorphous carbon layer through the trimmed photoresist layer to a predetermined depth that does not break through the amorphous carbon layer;
trimming the amorphous carbon layer into a predetermined critical dimension, wherein trimming also forms openings in the amorphous carbon layer;
etching the polysilicon layer through the openings in the trimmed amorphous carbon layer; and
forming a gate structure on the substrate.

19. The method of claim 18, wherein trimming the photoresist layer further comprises:
supplying a first trimming gas mixture having high selectivity to the photoresist layer over the amorphous carbon layer to trim the photoresist layer to a critical dimension less than about 55 nm.

20. The method of claim 19, wherein the first trimming gas further comprises a halogen containing gas.

21. The method of claim 19, wherein trimming the amorphous carbon layer further comprises:
supplying a second trimming gas mixture having high selectivity to the amorphous carbon layer over the polysilicon layer to trim the amorphous carbon layer to a critical dimension less than about 45 nm.

22. The method of claim 19, wherein the second trimming gas includes at least an oxygen containing gas and a hydrogen gas.
